(19) United States
(12) Patent Application Publication
(10) Pub. No.: US 2019/0025463 A1
(43) Pub. Date: Jan. 24, 2019

(54) SUBSTRATE-FORMED METASURFACE DEVICES

(71) Applicant: PRESIDENT AND FELLOWS OF HARVARD COLLEGE, Cambridge, MA (US)

(72) Inventors: Alan Jenting SHE, Somerville, MA (US); Shuyan ZHANG, Somerville, MA (US); Federico CAPASSO, Cambridge, MA (US)

(73) Assignee: PRESIDENT AND FELLOWS OF HARVARD COLLEGE, Cambridge, MA (US)

(21) Appl. No.: 16/040,488

(22) Filed: Jul. 19, 2018

Related U.S. Application Data
(60) Provisional application No. 62/534,658, filed on Jul. 19, 2017.

(51) Int. Cl. G02B 1/00; G03F 7/00; G02B 5/02; G02B 27/00; G02B 27/42; G02B 5/18

(52) U.S. Cl. CPC G02B 1/002; G03F 7/0005; G02B 5/1876; G02B 27/0025; G02B 27/4211; G02B 5/0226

(57) ABSTRACT

A method of fabricating an optical device and the associated optical device are disclosed. The optical device includes a metasurface and a substrate that are integrally formed by the same materials. The method comprises: forming a photoresist mask on a substrate, the photoresist mask defining a metasurface pattern based on an optical profile of a target optical device; generating metasurface features on the substrate, by etching away a portion of the substrate that is not covered by the photoresist mask; and producing the target optical device having the metasurface features, by removing the photoresist mask, wherein the metasurface features include a portion of a material of the substrate.

### CROSS-REFERENCE TO RELATED APPLICATIONS

This application claims the benefit of and priority to U.S. Provisional Patent Application 62/534,658, filed Jul. 19, 2017, which is incorporated herein by reference in its entirety.

### STATEMENT OF FEDERALLY SPONSORED RESEARCH OR DEVELOPMENT

This invention is made with Government support under FA9550-14-1-0389, awarded by Air Force Office of Scientific Research. The Government has certain rights in the invention.

### BACKGROUND

Conventional refractive optical components such as prisms and lenses are manufactured by glass polishing. The drawbacks include bulky sizes, high manufacturing costs and limited manufacturing precisions, which prevent the optical components from being used in various applications, particularly portable systems and conformal or wearable devices.

### SUMMARY

According to at least some embodiments of the present disclosure, a method of fabricating an optical device comprises: forming a photoresist mask on a substrate, the photoresist mask defining a metasurface pattern based on an optical profile of a target optical device; generating metasurface features on the substrate, by etching away a portion of the substrate that is not covered by the photoresist mask; and producing the target optical device having the metasurface features, by removing the photoresist mask, wherein the metasurface features include a portion of a material of the substrate.

According to at least some embodiments of the present disclosure, a method of fabricating an optical device comprises: depositing a layer of deformable material on a mold, the mold defining a metasurface pattern based on an optical profile of a target optical device; transferring the metasurface pattern to the layer of deformable material by deforming the layer of deformable material on the mold by an external influence; and generating the target optical device including a metasurface and a substrate by removing the mold, wherein the metasurface and substrate are formed by the layer of deformable material.

According to at least some embodiments of the present disclosure, an optical device comprises a substrate and a metasurface on the substrate. The metasurface includes a plurality of metasurface features. The metasurface features define an optical profile that adjusts phases, amplitudes, or polarizations of light beams. The substrate and the metasurface are integrally formed from a single material.

### BRIEF DESCRIPTION OF THE DRAWINGS

For a better understanding of the nature and objects of some embodiments of this disclosure, reference should be made to the following detailed description taken in conjunction with the accompanying drawings.

FIG. 1 illustrates an example of a silicon dioxide (SiO₂) based substrate-formed metasurface lens.

FIG. 2 illustrates an example method of designing and fabricating a substrate-formed metasurface device.

FIG. 3 illustrates schematic layouts of simulations of element libraries for metasurface devices.

FIG. 4 illustrates an example process of fabricating a substrate-formed metasurface using a resist mask based etching method.

FIG. 5 illustrates an example process of fabricating a substrate-formed metasurface using a hard mask based etching method.

FIG. 6 illustrates an example process of fabricating a substrate-formed metasurface using a photo-nanoimprint lithography (P-NIL) process.

FIG. 7 illustrates an example process of fabricating a substrate-formed metasurface through a thermal or pressure-based nanoimprint lithography process.

FIG. 8 illustrates a picture of a quartz photomask used with a deep ultraviolet stepper.

FIG. 9 illustrates a picture of a metasurface device during a reactive ion etching process of a hard mask method.

FIG. 10 illustrates a picture of substrate-formed SiO₂ multi-device metasurface lenses viewed in reflection.

FIG. 11 illustrates a picture of substrate-formed SiO₂ metasurface lenses.

FIG. 12 illustrates a picture of SiO₂ metasurface lenses on a wafer undergoing inspection by an optical microscope.

### DETAILED DESCRIPTION

Thin, flat devices such as planar optical elements (POEs) can replace bulky optical devices (e.g., lenses) with the same functionalities. POEs control the wavefront of light by using arrays of features such as fixed optical phase shifters, amplitude modulators, and/or polarization changing elements. The features of POEs are patterned on a surface to introduce a desired spatial distribution of optical phases, amplitudes, and/or polarizations of the light. Through the specific design, the POEs can achieve various functionalities of optical devices. For example, the POEs can manifest functionalities of, e.g., lenses, axicons, blazed gratings, vortex plates, wave plates, or a combination of two or more thereof.

In particular, the POEs can include a class of optical components called metasurfaces. A device that includes at least one metasurface is called metasurface device. The metasurfaces are based on small optical elements (also referred to as metasurface elements or metasurface features). The small optical elements may be spaced less than the distance corresponding to a wavelength of light apart. By reducing the spacing of these metasurface elements, diffraction orders (such as those seen in diffraction gratings or conventional diffractive optical elements) can be suppressed, thus improving performance, and in particular, efficiency of the metasurface device. The metasurfaces provide a versatile platform for locally modulating the phases, amplitudes, and/or polarizations of an incident wavefront. The metasurfaces may be used in various compact optical elements, e.g., lenses, polarimeters, axicons, holograms, etc.

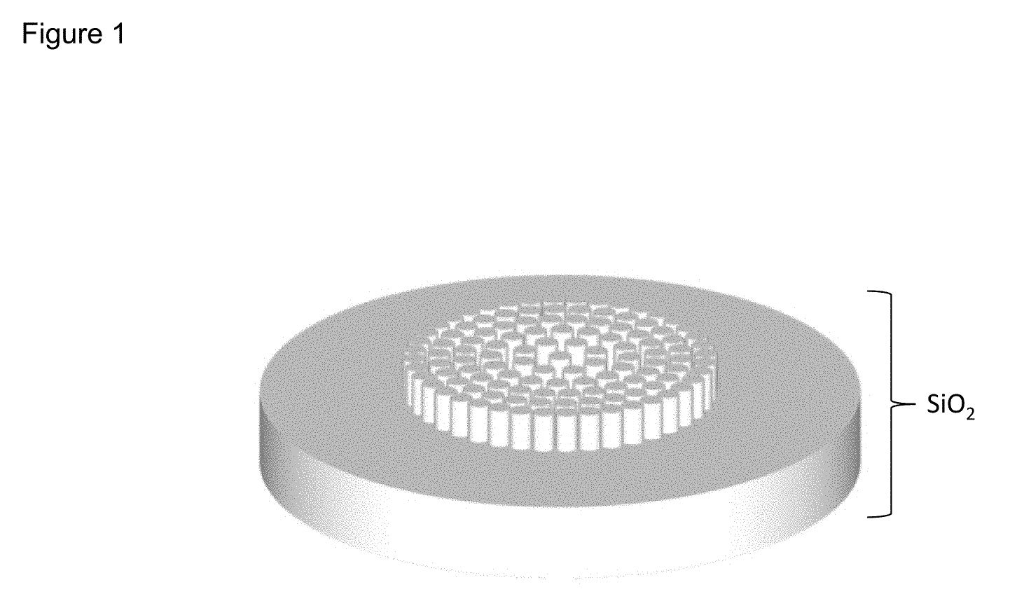

According to at least some embodiments of the present disclosure, metasurfaces can be directly patterned into the substrate material so that metasurface devices can be produced in an economic and efficient way. The substrate serves as the material bulk with which the metasurface is designed to be made, as well as the mechanical foundation and support for the metasurface itself. For example, a metasurface device can be a silicon dioxide (SiO₂) based metasurface lens. FIG. 1 illustrates an example of a silicon dioxide (SiO₂) based substrate-formed metasurface lens. The metasurface lens (including the substrate portion and the metasurface portion that are integrally formed) may be formed of SiO₂. The pattern of a metasurface is directly etched into the surface of, e.g., a SiO₂ (such as fused silica) wafer. Because the pattern of the metasurface lens is etched into the SiO₂ substrate through a lithographic process and an etching process, there is no need for additional material deposition on a substrate. The shape of the wafer for fabricating the substrate-formed metasurface lens can be the same or different from a shape of a comparative wafer. For example, the wafer can be in a form of a plate, a panel, a sheet, a disk, etc. The shape of the substrate may planar or non-planar. The boundary of the substrate may be circular, rectangular, or of any other shape. The substrate may be flexible, stretchable, and/or compliant to certain mechanical specifications.

In some embodiments, the material of the substrate includes, e.g., silicon dioxide, dielectric material, polymer, metal, transparent ceramic, doped silicon dioxide, BK7 glass, borofloat 33 glass, Corning Eagle glass, D263 glass, gorilla glass, single crystal quartz, soda lime glass, silicon, germanium, germanium dioxide, titanium dioxide, sapphire, silicon on insulator, silicon on sapphire, gallium nitride on sapphire, gallium arsenide, gallium phosphide, gallium antimonide, indium phosphide, indium antimonide, indium arsenide, indium gallium arsenide, silicon carbide, lithium niobate, lithium tantalate, vanadium dioxide, yttria alumina garnet, zirconium dioxide, or a combination of two or more thereof. The substrate may be made of a tunable material, such as one employing tuning effect. The tuning effect may include, piezoelectricity, piezomagnetism, electrostriction, magnetostriction, Pockels effect, other electrooptic effect, or a combination of two or more thereof.

In some comparative embodiments, metasurfaces may be made through the following stages. An optical profile (in terms of, e.g., phases, amplitudes, and/or polarizations) of the desired optical device is determined or calculated. For example, a phase profile of a lens following a hyperboloidal phase profile can be:

$$φ = - \frac{2 π}{λ} ( \sqrt{{f}^{2} + {r}^{2}} - f ) ;$$

where λ is the wavelength of light, r is the radial position measured from the center of the lens, and ƒ is the focal length of the lens. A material is chosen to form the metasurface. For brevity, this material may be referred to as the Material of Metasurface (MM). A metasurface element library is generated by computer simulations of a series of small optical structures with the MM. A computer-aided design (CAD) structure of the metasurface is generated using the optical profile and the metasurface element library. A transparent or non-interacting substrate is chosen. The device is fabricated during a fabrication process that involves depositing the MM on the substrate. The metasurface device may be further inspected, diced, and/or packaged.

The fabrication process can use various methods. The deposition of MM may occur before or after the lithographic step. For example, the fabrication process can use a resist mask method that includes depositing MM, coating resist, lithography, developing, etching, and removing resist. The fabrication process can also use a hard mask method that includes depositing MM, depositing hard mask material, coating resist, lithography, developing, etching, and removing resist. The fabrication process can also use a lift-off method that includes coating lift-off resist, lithography, depositing MM by directional deposition, and lifting off. The fabrication process can also use a fill-in method that includes coating resist, lithography, developing, depositing MM by conformal deposition, etching back extra MM, and removing resist.

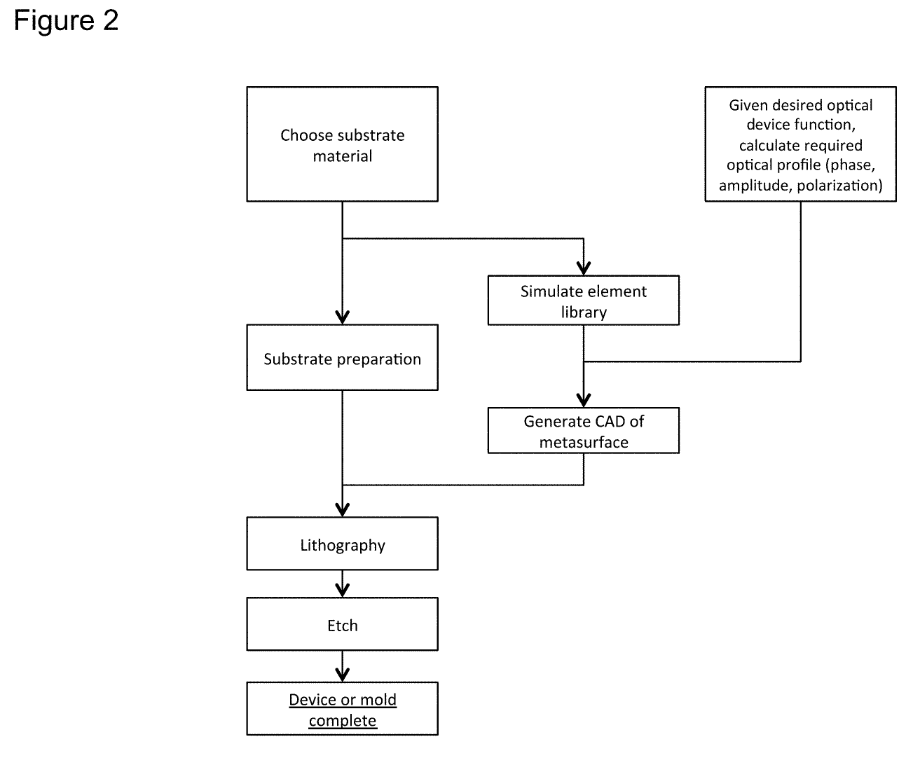

According to at least some embodiments of the present disclosure, the lithographic mask is deposited directly over the substrate and there is no need to deposit additional metasurface material on the substrate. FIG. 2 illustrates an example method of designing and fabricating a substrate-formed metasurface device. The optical profile (in terms of phases, amplitudes, and/or polarizations) of the desired optical device is determined or calculated. A material is chosen to form the metasurface, which is also the material of the substrate. The substrate and metasurface element can be made of the same material and can be contiguous. A metasurface element library is generated (e.g., by computer simulations) of a series of small optical structures with the material of substrate. A computer-aided design (CAD) structure of the metasurface is generated using the optical profile and the metasurface element library.

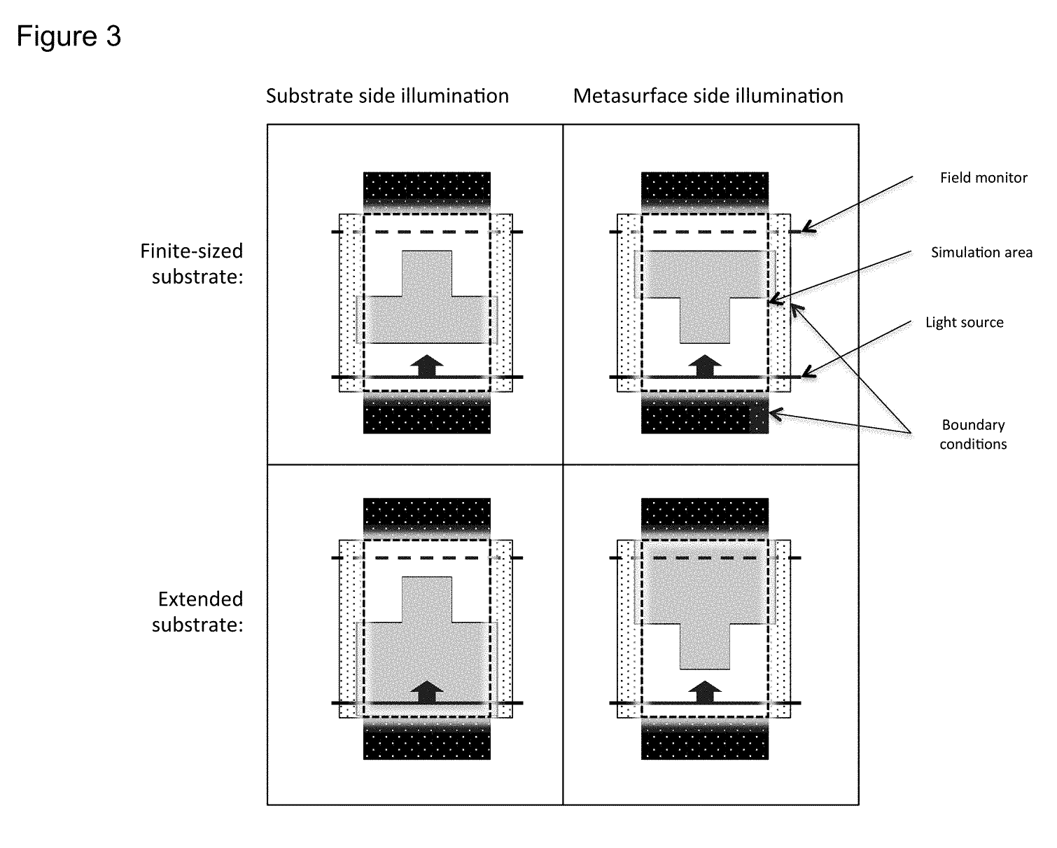

FIG. 3 illustrates schematic layouts of simulations of element libraries for metasurface devices operating in transmission modes. Within a simulation area, the metasurface element is defined such that it forms a single body the substrate. A light source (shown as a solid line) is positioned either on the substrate side or the metasurface side. A field monitor (shown as a dotted line) is positioned on the opposite side in order to measure the transmitted field. The data from the field monitor is used to extract the phase, amplitude, and/or polarization responses of the simulated structure. The boundary conditions are defined at the boundaries of the simulation area. In some embodiments, artificial absorbing layers such as perfectly matched layers (PML) may be defined at the boundaries in the direction of light propagation. In some embodiments, the boundary conditions at the boundaries perpendicular to the direction of light propagation may be, e.g., periodic or conforming to Bloch boundary conditions.

The fabrication process can use various methods such as resist mask method or hard mask method. For example, the fabrication process can use a resist mask method that includes coating resist, lithography, developing, etching, and removing resist. The fabrication process can also use a hard mask method that includes depositing hard mask material, coating resist, lithography, developing, etching, and removing resist. The metasurface device may be further inspected, diced, and/or packaged.

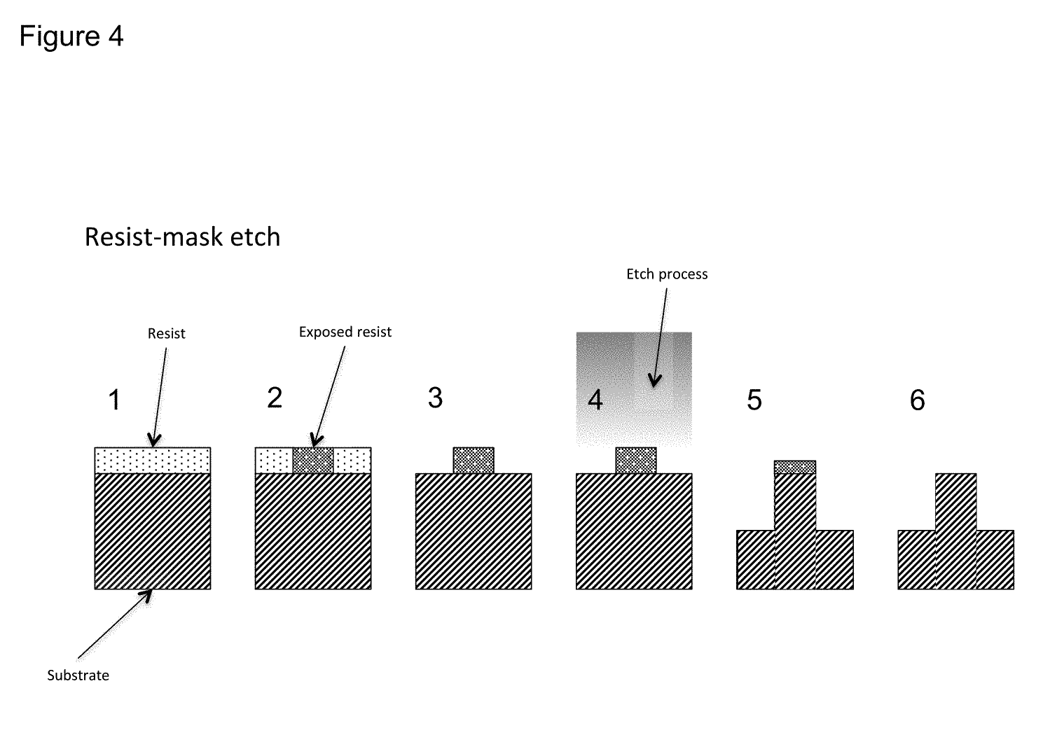

FIG. 4 illustrates an example process of fabricating a substrate-formed metasurface using a resist mask based etching method. The substrate is prepared by, e.g., coating a layer of resist (such as photoresist). The layer of resist may internally include additional layers such as adhesion layers and antireflection coatings to improve feature fidelity in the lithographic process. The prepared substrate undergoes lithography, such as deep UV photolithography, to expose the resist. The sample is developed and undergoes an etching process, such as deep reactive ion etching (deep RIE). The desired pattern is etched directly into the substrate itself. The remaining resist is removed to form the substrate-formed metasurface device.

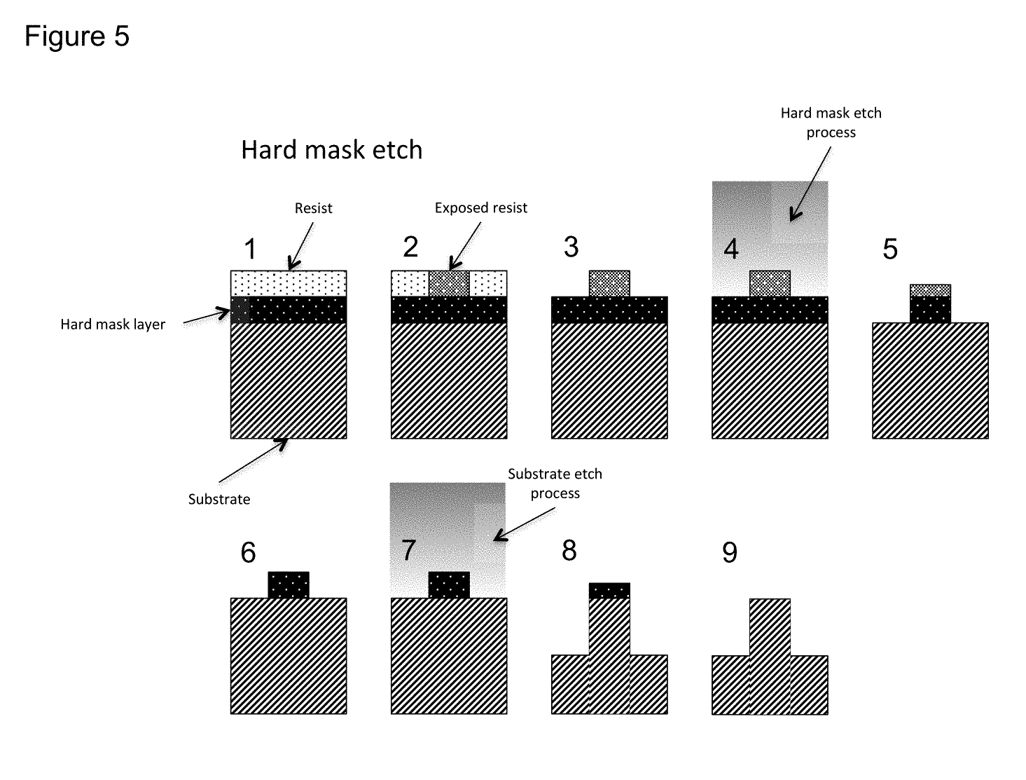

FIG. 5 illustrates an example process of fabricating a substrate-formed metasurface using a hard mask based etching method. The substrate is prepared by, e.g., depositing a thin layer of material which acts as a hard mask and also coating a layer of resist, such as photoresist. The layer of resist may internally include additional layers such as adhesion layers and antireflection coatings to improve feature fidelity in the lithographic process. The prepared substrate undergoes lithography, such as deep UV photolithography, to expose the resist. The sample is developed and undergoes an etching process, such as a chlorine etching, to transfer the pattern to the hard mask. The pattern is transferred to the hard mask. The resist is removed. A second etch step is performed to transfer the pattern into the substrate. Due to the difference between etch rates of the hard mask and the substrate, high aspect ratios can be achieved. The desired pattern is then etched directly into the substrate itself. The remaining hard mask is removed to form the substrate-formed metasurface device.

During the fabrication processes of FIGS. 4 and 5, there is no deposition of MM over the substrate, because the substrate material is used to form the metasurface features. In some embodiments, the lithography may be performed with a high throughput using, e.g., a projection stepper or scanner.

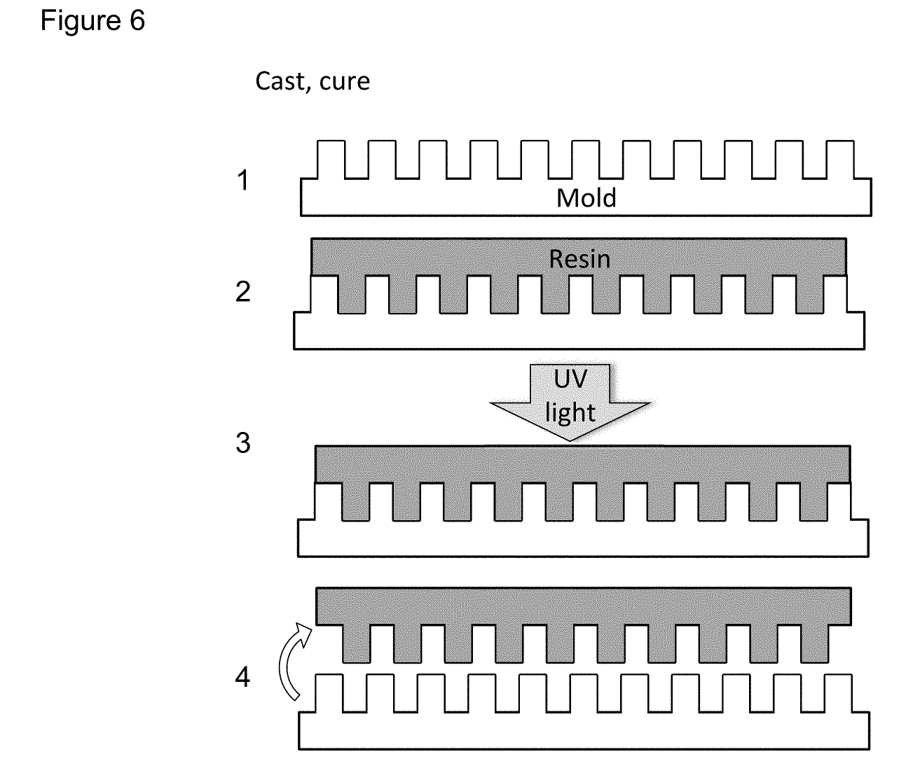

In some embodiments, a mold of a device can be manufactured by, e.g., the resist mask method or the hard mask method mentioned above. A substrate-formed metasurface device can be formed based on the mold using, e.g., a nanoimprint lithography process. FIG. 6 illustrates an example process of fabricating a substrate-formed metasurface using a photo-nanoimprint lithography (P-NIL) process. For example, a desired photocurable resin (such as the resin used in photo-nanoimprint lithography) can be casted into a mold of a desired metasurface design. The mold is cured by, e.g., irradiation of a suitable spectrum. The metasurface device is released from the mold. The metasurface device is formed on the mold so that the substrate and metasurface are formed as a single material body as shown in FIG. 6.

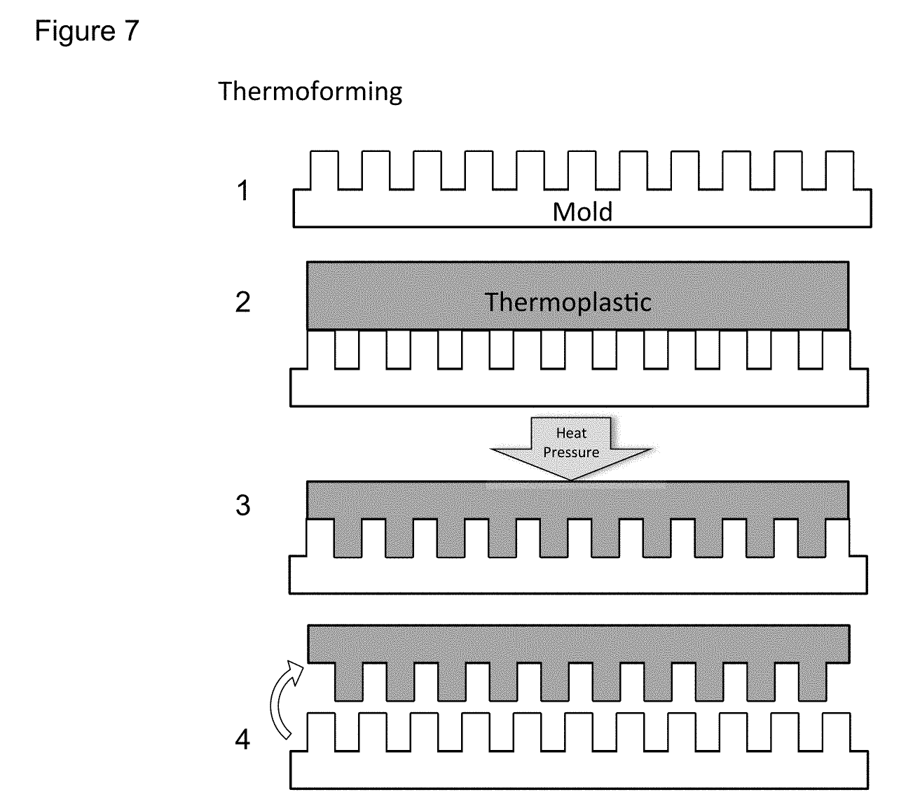

In some embodiments, the metasurface device can also be manufactured by, e.g., applying heat and/or pressure to a layer of material (such as thermoplastic). FIG. 7 illustrates an example process of fabricating a substrate-formed metasurface through a thermal or pressure-based nanoimprint lithography process. A layer of material (e.g. thermoplastic) is applied onto a mold of a desired metasurface design. The layer of material (e.g., thermoplastic) is reshaped under the application of heat and/or pressure (such as thermoforming nanoimprint lithography, vacuum forming, or injection molding), into a mold of a desired metasurface design. The metasurface device is formed on the mold so that the substrate and metasurface are formed as a single material body as shown in FIG. 7. In some embodiments, the metasurface device fabricated by the nanoimprint lithography process as illustrated in FIGS. 6 and 7 may be mass produced in a roll-to-roll manner.

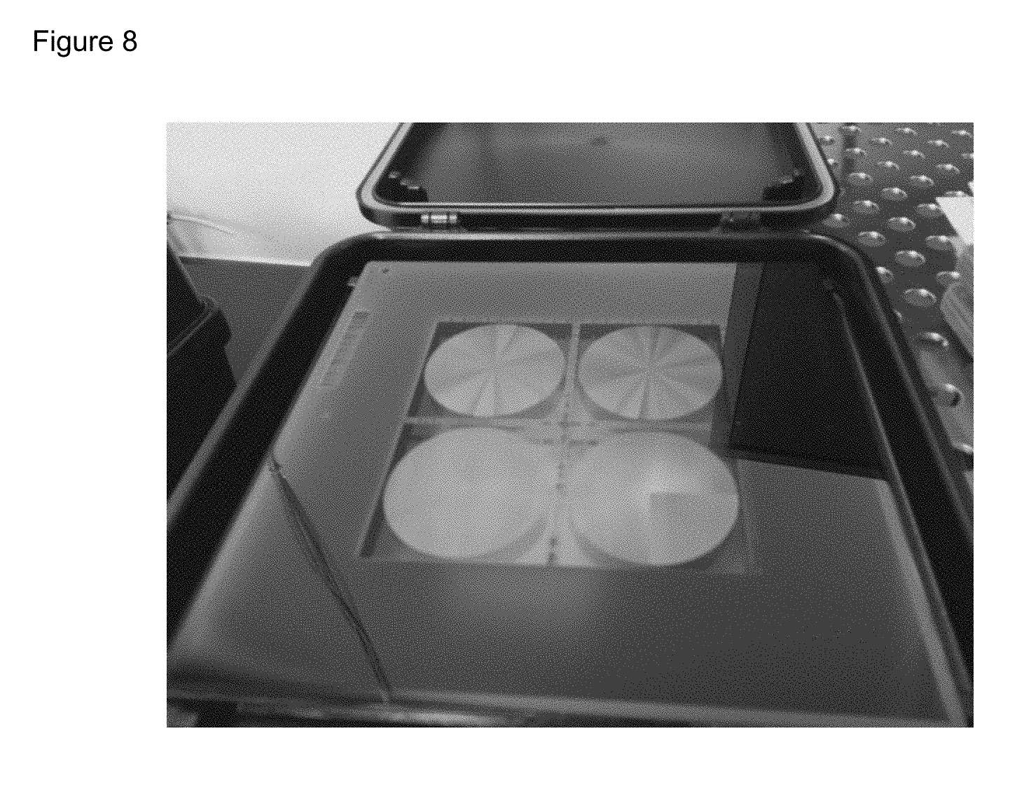

FIG. 8 illustrates a picture of a quartz photomask used with a deep ultraviolet stepper. The photomask may include four different metasurface devices, all of which can be exposed simultaneously or individually during photolithography.

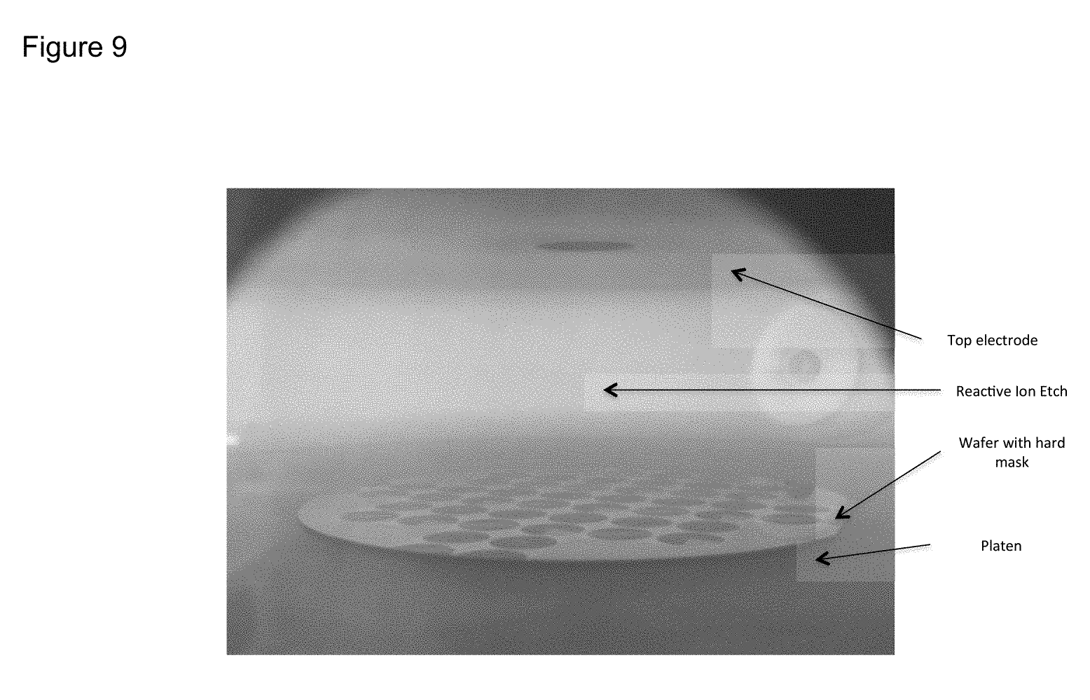

FIG. 9 illustrates a picture of a metasurface device during a reactive ion etching process of a hard mask method. The metasurface device, which may include a chromium-based hard mask over SiO₂ substrate, allows for high aspect ratio etch profiles, since SiO₂ is etched much more quickly than the chromium hard mask. During the etching, the pattern is etched directly into substrate, so that the metasurface and substrate can be made of a single material and can integrally form a single contiguous body.

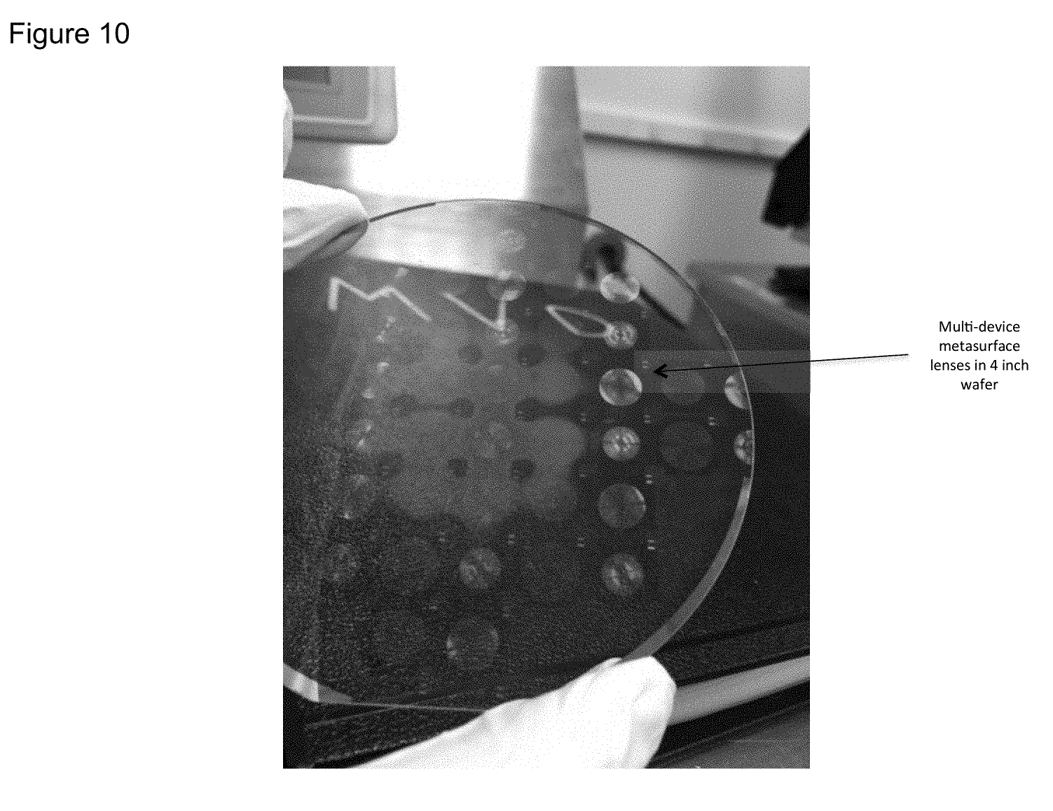

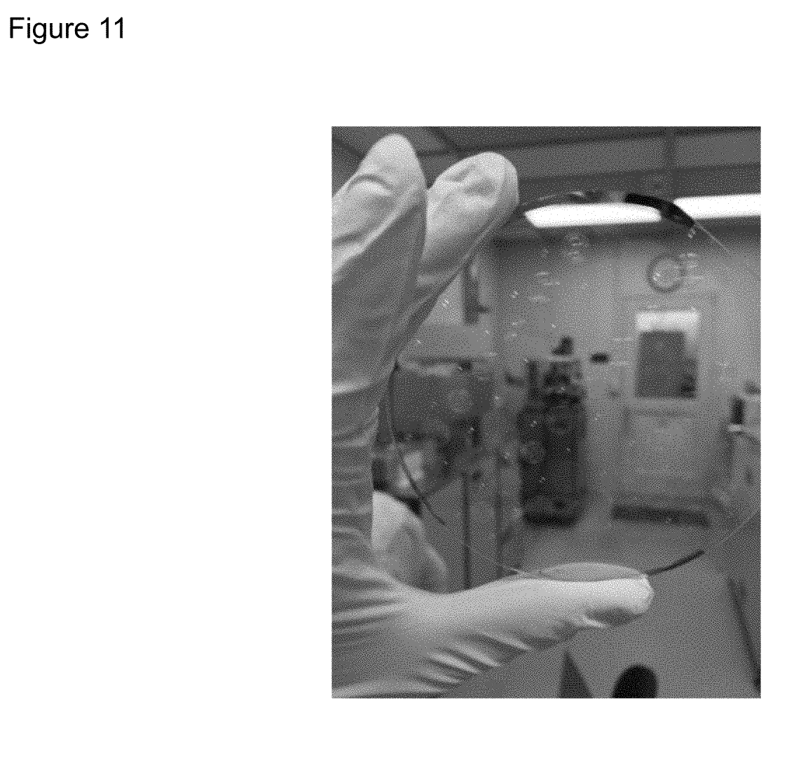

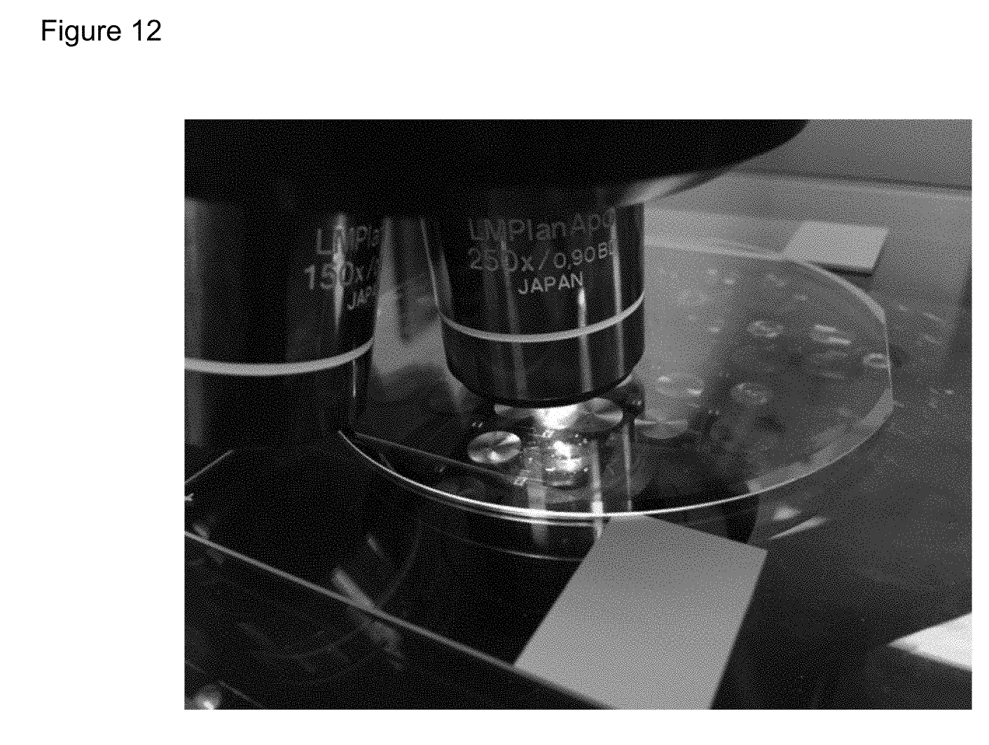

FIG. 10 illustrates a picture of substrate-formed SiO₂ multi-device metasurface lenses viewed in reflection. FIG. 10 also shows a wafer containing the multiple devices being fabricated simultaneously. FIG. 11 illustrates a picture of substrate-formed SiO2 metasurface lenses. FIG. 12 illustrates a picture of SiO₂ metasurface lenses on a wafer undergoing inspection by an optical microscope.

The disclosed technology fabricates metasurface devices in a streamlined and economical process and allows long sought-after applications of the metasurface devices. At least in some embodiments of the present disclosure, the fabrication process as disclosed does not include depositing an additional layer of material on the substrate for forming the metasurface. In addition to economic concerns, additional steps in a long and complicated comparative fabrication process may introduce more room for error and in turn a higher probability of reduction in desired optical performance. The disclosed technology provides an avenue for increased yield and better performance for the metasurface devices since there is no deposition of separate metasurface material. Furthermore, the substrate may serve dual purposes as both the mechanical support of the metasurface and the metasurface itself with the desired optical functionalities. The disclosed technology allows for manufacturing low cost, high yield metasurface devices, such as flat optical lenses for, e.g., eyeglasses, cameras, satellite imaging, microscopes, telescopes for astronomy, etc. One example of a metasurface device can be SiO₂ metasurface lenses made directly in SiO₂ wafers using a lithography process and an etching process.

In some embodiments, the metasurface device as disclosed may operate in transmission mode and/or reflection mode. The metasurface device may be designed for any suitable wavelength or range of wavelengths in an electromagnetic spectrum. The wavelength range may include, but not limited to, radio spectrum, infrared spectrum, and visible spectrum. The metasurface device may operate for a narrow band a single wavelength, or a broad band or multiple wavelengths. The wavelengths may in the visible, near-infrared, mid-infrared, far-infrared or other spectrums.

In some embodiments, the metasurface device or the POE as disclosed may be designed to accept light with any state of polarization, such as well-defined polarization such as linear, circular or elliptical polarizations, unpolarized light, or partially polarized light. The metasurface device or the POE may or may not perform a separate action on the orthogonal polarization.

In some embodiments, the metasurface device may include a structure that defines any arbitrarily defined spatial pattern. The spatial pattern determines, at each location in the pattern, phase (or geometric phase), amplitude, and/or polarization of the light. The metasurface device may be various optical devices, such as focusing element (lens or axicon), beam deflector (e.g., linear phase gradient), phased array or metasurface, photonic crystal, hologram, diffraction grating, multifocal diffractive lens, polarizer, beam splitter (polarizing or non-polarizing), depolarizer, diffuser, optical attenuator (e.g., neutral density filter, bandpass filter, edgepass filter), Fabry-Perot resonator, retroreflector, wave plate or retarder (e.g., array of birefringent elements comprising a phase plate), Fresnel zone plate (e.g., a Fresnel imager or Fresnel zone antenna), aperture (e.g., pinhole, iris, diaphragm, or pupil), or a combination of two or more thereof.

In some embodiments, the metasurface device may be used in various applications. For example, the metasurface device may be used in electrically-tunable lenses. The electrically-tunable lenses include, e.g., corrective lenses (e.g., eyeglasses, or contact lenses), magnifiers (e.g., magnifying glass, microscopes, beam expander), photographic lenses (e.g., varifocal lens, zoom lens, fisheye lens, anamorphic lens, mirror lens such as catadioptric lens or reflex lens, corrector plates, full aperture correctors, sub-aperture correctors, aberration correctors, perspective control lens, lenses used to introduce optical special effects such as soft focus lens, stereoscopic lens, projection lens (such as lenses used in image or video projection, photographic reduction or photolithography), or a combination of two or more thereof.

In some embodiment, the metasurface device may be used as being stacked in configurations with multiple electronically tunable flat lenses. For example, the focal lengths of all the stacked lenses may be tuned, or some lenses are tuned and some are not tuned. Some lenses may be tunable and some lenses may not be tunable. The distance of separation between lenses may be fixed or variable by, e.g. action of an ultrasonic motor (e.g., piezoelectric motor, stepper motor, or other linear motors). The effective variable focus of the lens may be enhanced by the multiple-lens configuration. In some embodiments, a parfocal lens may be constructed, for which the focal plane is unchanged while the magnification is changed. In other words, the lens may be an ideal zoom lens, or independent and/or separate control over focus and magnification may be maintained. The independent and/or separate control over focus and magnification may operate in conjunction so that final aberrations are reduced, such as spherical aberration, chromatic aberration, and coma.

In some embodiments, the metasurface device may be used in conjunction with conventional bulky lenses or mirrors as part of a compound lens optical system.

In some embodiments, the metasurface device may be used in an imaging system. For example, the focusing mechanism may be implemented through electrical control. The control may be a manual focusing mechanism such as a wheel, button, screw, switch, slider, or computer control etc. that allows for manual tuning of the voltage and hence the focal length. The control may be an electrical feedback mechanism that adjusts the voltage across the lens and hence the focal length in order to perform autofocusing. The autofocusing may be achieved by, e.g., measuring the distance from the imaging system to the object by means of sound waves (e.g. ultrasonic) or light (e.g. infrared), phase detection by closed-loop control or open-loop control, contrast detection, assist lamp (e.g. an autofocus illuminator) to provide extra light in performing phase detection or contrast detection, or a combination of two or more thereof. The control may be a hybrid autofocus system in which autofocus is achieved by a combination of autofocus mechanisms. The control may be a control system to perform trap focus (e.g., focus trap or catch-in-focus) in which the action of a subject moving into the focal plane activates the acquisition of an image. The control may be a control system that maintains focus on a subject of interest (e.g., focus tracking) by adjusting the voltage and hence the focus in accordance with the distance or appearance of the subject. In some embodiment, in the imaging system, the focus or focal plane is scanned across multiple lengths in a continuous or discrete manner. A confocal microscope configuration may be used in the imaging system to perform, e.g., three-dimensional imaging.

In some embodiments, the metasurface device may be used in communications. For example, the metasurface device may be used in a way that the degree of defocusing or power transmitted is used to encode information.

In some embodiments, the metasurface device may be used in electrically-tunable optical systems. Such electrically-tunable optical systems may include, e.g., catoptric (e.g., reflection-based) systems, dioptric (e.g., transmission-based) systems, catadioptric (e.g., hybrid reflection and transmission based) systems, photographic cameras, cell phone cameras, video cameras, searchlights, headlamps, optical telescopes, microscopes, telephoto lens, microlens array, head-mounted optics systems, or combination of two or more thereof.

In some embodiments, the metasurface device may be used in other electrically-tunable optical devices and systems. Such electrically-tunable optical devices and systems may include, e.g., fiber coupler, variable coupler, mode converter, collimator, optical modulator, optical phase shifter, polarization state generator, polarimeter, ellipsometer, spectrometer, interferometer, optical chopper, fast change optical filters, optical tweezer, phase compensation, adaptive optics, noise eater or laser amplitude stabilizer, vortex plates for generating light beams with orbital angular momentum, Q plates generating orbital angular momentum of light (OAM), optical power concentrator, optical disc drive, or a combination of two or more thereof.

In some embodiments, the metasurface device may be used in applications including, but not limited to, e.g., image sensors, cameras, endoscopes, machine vision applications, phased arrays, lasers, lenslet arrays, lithotripsy, medical imaging, dichroic filters and/or mirrors, or a combination or two or more thereof.

In some embodiments, other than POEs, the metasurface device as disclosed may be analogously designed as planar acoustic elements (PAEs), such as by the use of acoustic metamaterials, in order to shape the wavefront of acoustic waves, such as ultrasonic waves.

It is to be understood that the term “design” or “designed” (e.g., as used in “design wavelength,” “design focal length” or other similar phrases disclosed herein) refers to parameters set during a design phase; which parameters after fabrication may have an associated tolerance.

As used herein, the singular terms “a,” “an,” and “the” may include plural referents unless the context clearly dictates otherwise.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated by such arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A method of fabricating an optical device, comprising:
forming a photoresist mask on a substrate, the photoresist mask defining a metasurface pattern based on an optical profile of a target optical device;
generating metasurface features on the substrate, by etching away a portion of the substrate that is not covered by the photoresist mask; and
producing the target optical device having the metasurface features, by removing the photoresist mask, wherein the metasurface features include a portion of a material of the substrate.

2. The method of claim 1, wherein the metasurface features define the optical profile that adjusts phases, amplitudes, or polarizations of light beams propagating through the metasurface features.

3. The method of claim 1, wherein the forming the photoresist mask comprises:
depositing a layer of photoresist on the substrate; and
transferring the metasurface pattern to the layer of photoresist though a lithography process.

4. The method of claim 3, wherein the removing the photoresist mask comprises:
removing the layer of photoresist.

5. The method of claim 3, wherein the layer of photoresist comprises an adhesion layer or an antireflection layer.

6. The method of claim 1, wherein the forming the photoresist mask comprises:
depositing a layer of hard mask on the substrate;
depositing a layer of photoresist on the layer of hard mask;
transferring the metasurface pattern to the layer of photoresist, by a lithography process;
transferring the metasurface pattern to the layer of hard mask, by etching away a portion of the layer of hard mask based on the metasurface pattern of the layer of photoresist; and
removing the layer of photoresist.

7. The method of claim 6, wherein the removing the photoresist mask comprises:
removing the layer of hard mask.

8. The method of claim 6, wherein aspect ratios of the metasurface features depend on a relationship between an etch rate of the layer of hard mask and an etch rate of the substrate.

9. The method of claim 1, further comprising:
determining the metasurface pattern based on the optical profile of the target optical device and the material of the substrate.

10. The method of claim 1, wherein the photoresist mask is formed on a substrate using a lithography process.

11. The method of claim 10, wherein the lithography process is performed by a projection stepper or scanner.

12. A method of fabricating an optical device, comprising:
depositing a layer of deformable material on a mold, the mold defining a metasurface pattern based on an optical profile of a target optical device;
transferring the metasurface pattern to the layer of deformable material by deforming the layer of deformable material on the mold by an external influence; and
generating the target optical device including a metasurface and a substrate by removing the mold, wherein the metasurface and substrate are formed by the layer of deformable material.

13. The method of claim 12, wherein the layer of deformable material includes a temperature-sensitive material, and the external influence includes an application of heat.

14. The method of claim 12, wherein the layer of deformable material includes a pressure-sensitive material, and the external influence includes an application of pressure.

15. The method of claim 12, wherein the layer of deformable material includes a photocurable resin, and the external influence includes a lithography process.

16. The method of claim 15, wherein the lithography process includes a photo-nanoimprint lithography process.

17. The method of claim 12, wherein the depositing the layer of deformable material comprises:
depositing the layer of deformable material on the mold in a roll-to-roll process, the mold defining the metasurface pattern based on the optical profile of the target optical device.

18. An optical device, comprising:
a substrate; and
a metasurface on the substrate including a plurality of metasurface features, the metasurface features defining an optical profile that adjusts phases, amplitudes, or polarizations of light beams;
wherein the substrate and the metasurface are integrally formed from a single piece of material.

19. The optical device of claim 18, wherein the substrate and the metasurface form a single continuous or homogeneous body.

20. The optical device of claim 18, wherein the substrate and the metasurface include silicon dioxide, dielectric material, polymer, metal, transparent ceramic, composite material, such as doped silicon dioxide, BK7 glass, borofloat 33 glass, Corning Eagle glass, D263 glass, gorilla glass, single crystal quartz, soda lime glass, silicon, germanium, germanium dioxide, titanium dioxide, sapphire, silicon on insulator, silicon on sapphire, gallium nitride on sapphire, gallium arsenide, gallium phosphide, gallium antimonide, indium phosphide, indium antimonide, indium arsenide, indium gallium arsenide, silicon carbide, lithium niobate, lithium tantalate, vanadium dioxide, yttria alumina garnet, or zirconium dioxide.

21. The optical device of claim 18, wherein the optical profile defined by the metasurface features comprises a profile of a focusing lens or axicon, a beam deflector, a phased array or metasurface, a photonic crystal, a hologram, a diffraction grating, a multifocal diffractive lens, a polarizer, a beam splitter, a depolarizer, a diffuser, an optical attenuator, a Fabry-Perot resonator, a retroreflector, a wave plate or retarder, a Fresnel zone plate, or an aperture.
